(19) United States
(12) Patent Application Publication
(10) Pub. No.: US 2020/0181798 A1
(43) Pub. Date: Jun. 11, 2020

(54) SUSCEPTOR AND CHEMICAL VAPOR DEPOSITION APPARATUS

(71) Applicant: SHOWA DENKO K.K., Tokyo (JP)

(72) Inventors: Yuichiro MABUCHI, Chichibu-shi (JP); Keisuke FUKADA, Chichibu-shi (JP)

(73) Assignee: SHOWA DENKO K.K., Tokyo (JP)

(21) Appl. No.: 16/705,848

(22) Filed: Dec. 6, 2019

(30) Foreign Application Priority Data
Dec. 10, 2018 (JP) 2018-230897

(51) Int. Cl. C30B 25/12; C23C 16/458; C23C 16/46; C30B 29/36; C23C 16/32; H01L 21/687

(52) U.S. Cl. CPC C30B 25/12; C23C 16/4583; C23C 16/46; H01L 21/68785; C23C 16/325; H01L 21/68735; C30B 29/36

(57) ABSTRACT

A susceptor, including: a base portion having a first surface on which a wafer is placed, in which the base portion has a plurality of openings which penetrate through the base portion in a thickness direction and supply an Ar gas to a back surface of the wafer.

### BACKGROUND OF THE INVENTION

### Field of the Invention

The present invention relates to a susceptor and a chemical vapor deposition apparatus.

Priority is claimed on Japanese Patent Application No. 2018-230897, filed on Dec. 10, 2018, the content of which is incorporated herein by reference.

### Description of Related Art

Silicon carbide (SiC) has properties including a dielectric breakdown electric field of one digit larger, a band gap of three times larger, and thermal conductivity of three times higher than those of silicon (Si). Since SiC has these properties, silicon carbide is expected to be applied to a power device, a high-frequency device, a high-temperature operation device, and the like. Therefore, in recent years, a SiC epitaxial wafer has been used for the above semiconductor devices.

A SiC epitaxial wafer is manufactured by growing a SiC epitaxial film, which becomes an active region of a SiC semiconductor device, on a SiC substrate. The SiC substrate is obtained by processing from a SiC bulk single crystal produced by a sublimation method or the like, and the SiC epitaxial film is formed by chemical vapor deposition (CVD).

In this specification, the SiC epitaxial wafer means a wafer after formation of the SiC epitaxial film, and the SiC wafer means a wafer before formation of the SiC epitaxial film.

For example, Japanese Unexamined Patent Application, First Publication No. 2016-50164 describes a chemical vapor deposition apparatus which laminates a SiC epitaxial film. The SiC epitaxial film is formed on a SiC wafer placed on a susceptor.

For example, Japanese Unexamined Patent Application, First Publication No. 2009-70915 describes a susceptor which is used in a chemical vapor deposition apparatus. The susceptor described in Japanese Unexamined Patent Application, First Publication No. 2009-70915 has a separation structure in which an inner susceptor and an outer susceptor are separated. A gap is formed between the inner susceptor and the outer susceptor.

### SUMMARY OF THE INVENTION

However, in a case where a conventional susceptor is used, a back surface on the opposite side of a surface on which the SiC epitaxial film is laminated may roughen in the SiC epitaxial wafer after formation of the SiC epitaxial film.

The roughness of the back surface generated in the SiC epitaxial wafer causes a haze and becomes a cause of defocusing during surface inspection. In addition, it becomes a cause of peeling of the back oxide film in the production of a SiC device. The roughness of the back surface of the SiC epitaxial wafer can be eliminated by polishing the back surface of the SiC epitaxial wafer. However, in a case where a step of polishing the back surface is added, the production process is increased and the throughput is decreased.

The present invention is contrived in view of the above circumstances, and an object thereof is to provide a susceptor capable of suppressing the roughness of a back surface of a wafer in the formation of an epitaxial film on the wafer by chemical vapor deposition.

The inventors have conducted intensive studies, and as a result, found that the occurrence of the roughness of a back surface of a wafer can be suppressed by allowing an inert gas to flow to the back surface of the wafer.

That is, the present invention provides the following apparatus in order to solve the above problems.

(1) A susceptor according to a first aspect of the present invention includes: a base portion having a first surface on which a wafer is placed, in which the base portion has a plurality of openings which penetrate through the base portion in a thickness direction and supply an Ar gas to a back surface of the wafer.

(2) In the susceptor according to (1), the base portion may be provided with a main body and a protrusion, the plurality of openings may be provided in the main body, and the protrusion may protrude from the main body in a thickness direction and may be provided at an outer periphery of the base portion.

(3) In the susceptor according to (1) or (2), the plurality of openings may be arranged along a plurality of virtual circles existing concentrically from a center in plan view of the first surface.

(4) In the susceptor according to (3), a distance between the adjacent virtual circles may be 10 mm or less.

(5) In the susceptor according to (3) or (4), some of the plurality of openings may be provided as a circular ring opening which continues along the virtual circle.

(6) In the susceptor according to any one of (3) to (5), some of the plurality of openings may be provided as through-holes which are scattered along the virtual circle.

(7) In the susceptor according to any one of (1) to (6), at least some of the plurality of openings may have a long axis in plan view.

(8) In the susceptor according to any one of (1) to (7), the opening may have a width of 1 mm or less.

(9) A susceptor according to a second aspect of the present invention which is used in a chemical vapor deposition apparatus which grows an epitaxial film on a main surface of a wafer by chemical vapor deposition includes: a first surface on which the wafer is placed; and an opening which penetrates through the susceptor in a thickness direction toward the first surface and supplies a rare gas to the wafer, in which the opening is a spiral opening formed in a spiral shape from a center toward an outer periphery in plan view of the first surface.

(10) In the susceptor according to (9), a distance in a radial direction between the adjacent spiral openings may be 10 mm or less.

(11) A chemical vapor deposition apparatus according to a third aspect of the present invention includes: the susceptor according to the first or second aspect.

A susceptor of the present invention can suppress the roughness of a back surface of a wafer in the formation of an epitaxial film on the wafer by chemical vapor deposition.

### BRIEF DESCRIPTION OF THE DRAWINGS

FIG. 1A is a schematic cross-sectional view of an example of a susceptor according to an embodiment.

FIG. 1B is a schematic cross-sectional view of an example of the susceptor according to an embodiment.

FIG. 2 is a schematic plan view of an example of a susceptor according to an embodiment.

FIG. 3 is a schematic plan view of an example of a susceptor according to an embodiment.

FIG. 4 is a schematic plan view of an example of a susceptor according to an embodiment.

FIG. 5 is a schematic plan view of an example of a susceptor according to an embodiment.

FIG. 6 is a schematic plan view of an example of a susceptor according to an embodiment.

FIG. 7 is a schematic plan view of an example of a susceptor according to an embodiment.

FIG. 8 is a schematic cross-sectional view of a chemical vapor deposition apparatus according to an embodiment.

FIG. 9 is a graph showing the distribution of the roughness of a back surface of a SiC epitaxial wafer grown using a susceptor having a circular ring-like opening.

FIG. 10 is a graph showing the distribution of the roughness of a back surface of a SiC epitaxial wafer grown using a susceptor having a circular opening.

FIG. 11 is a graph showing the surface temperature distribution of SiC epitaxial wafers during growing.

### DETAILED DESCRIPTION OF THE INVENTION

Hereinafter, a susceptor will be described in detail with appropriate reference to the drawings. In the drawings used in the following description, characteristic portions may be shown in an enlarged manner, and dimension ratios of the constituent components may be different from actual dimension ratios for easy understanding of the features of the present invention. The materials, dimensions, and the like exemplified in the following description are merely examples. The present invention is not limited thereto, and can be appropriately modified and implemented within the scope capable of achieving the effect of the present invention.

<Susceptor>

### First Embodiment

A susceptor according to the present embodiment is used in a chemical vapor deposition apparatus which grows an epitaxial film on a main surface Wa of a wafer W by chemical vapor deposition.

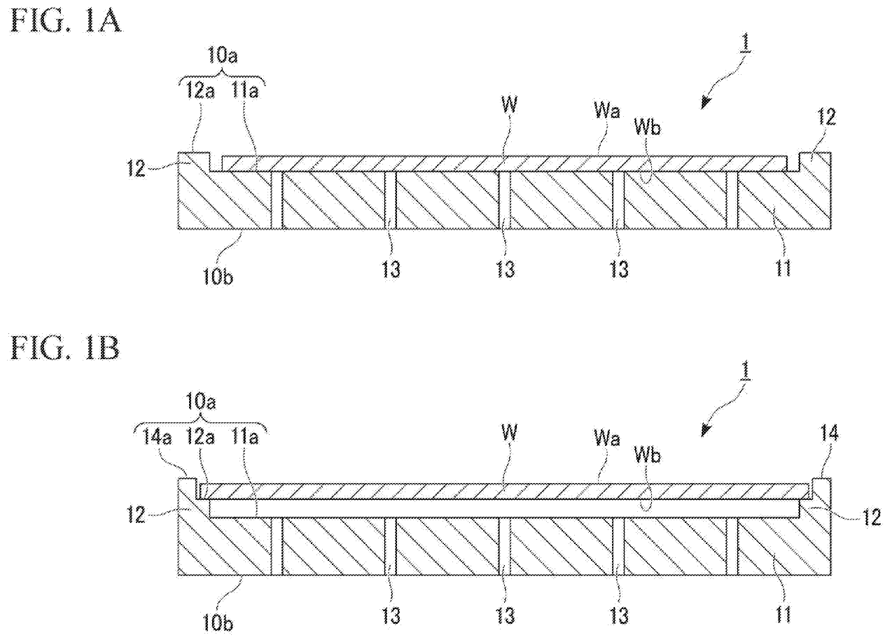

FIGS. 1A and 1B are cross-sectional views of a susceptor according to a first embodiment. FIGS. 1A and 1B show a state in which a wafer W is placed on the susceptor 1. A configuration in which the wafer W is placed on a main body 11 as shown in FIG. 1A, or a configuration in which the wafer W is placed on a protrusion 12 as shown in FIG. 1B may be employed. The wafer W is preferably placed on the protrusion 12.

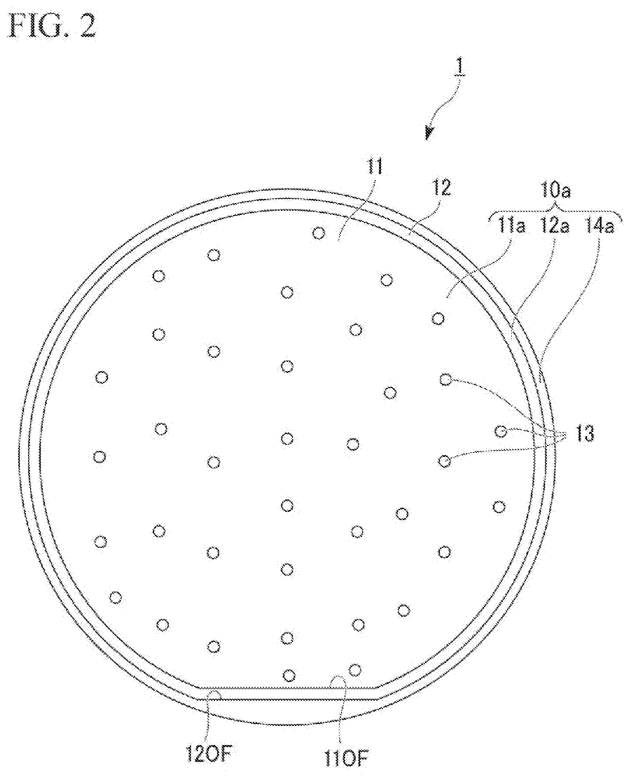

The susceptor 1 has a base portion. The base portion has the main body 11, the protrusion 12, and an outer peripheral protrusion 14. The base portion extends in a direction substantially parallel to the wafer W to be placed. The protrusion 12 protrudes from the main body 11 in a direction substantially orthogonal thereto. The protrusion 12 is positioned in an outer peripheral region of the base portion as shown in FIG. 2. The outer peripheral protrusion 14 protrudes from an upper surface of the protrusion 12 in a direction substantially orthogonal thereto. The outer peripheral protrusion 14 prevents the wafer W placed on the susceptor 1 from falling out in a radial direction.

In the present embodiment, the direction in which the wafer W is placed on the susceptor 1 is defined as a first direction, and the direction opposite to the first direction is defined as a second direction.

The susceptor 1 has a first surface 10a and a second surface 10b. The first surface 10a is a surface of the susceptor 1 in the first direction. The first surface 10a includes a first surface 11a of the main body 11, a first surface 12a of the protrusion 12, and a first surface 14a of the outer peripheral protrusion 14. The second surface 10b is a surface on the opposite side of the first surface 10a. A heater or the like which heats the wafer W is disposed below the second surface 10b.

The susceptor 1 has a plurality of openings 13. The openings 13 penetrate the susceptor 1 from the first surface 10a to the second surface 10b to form through-holes. Each of the plurality of openings 13 supplies a rare gas toward a back surface Wb of the wafer W. The rare gas is, for example, an Ar gas. As the rare gas, for example, an Ar gas, which is supplied to the second surface 10b of the susceptor 1 to protect the heater for heating the susceptor, can be used.

The cross-sectional shape of the opening 13 is not particularly limited. Each of the openings 13 shown in FIGS. 1A and 1B is linearly formed in a thickness direction. The opening 13 may be bent in the midway in the thickness direction. The opening 13 may be inclined inward or outward in the radial direction of the susceptor 1. The flow direction of the rare gas can be controlled by inclining the opening 13 inward or outward in the radial direction. The rare gas can be sufficiently supplied to the whole back surface Wb of the wafer W by supplying the rare gas inward or outward in the radial direction from the respective openings 13 in order.

FIG. 2 is a plan view of the susceptor 1 according to the first embodiment. The susceptor 1 is configured to have a substantially circular shape in plan view, as shown in FIG. 2. The first surface 11a of the main body 11 preferably has a substantially circular shape having a linear portion 11OF. The first surface 12a of the protrusion 12 preferably has a substantially ring shape having a linear portion 12OF. The linear portions 11OF and 12OF are provided in accordance with an orientation flat (hereinafter, referred to as an orientation flat) of the wafer W. A configuration in which the first surface 11 a of the main body 11 does not have the linear portion 11OF may be employed. A configuration in which the first surface 12a of the protrusion 12 does not have the linear portion 12OF may be employed. In a case where the wafer W has no orientation flat, the first surface 11a of the main body 11 may have a substantially circular shape and the first surface 12a of the protrusion 12 may have a substantially annular shape.

The number of the plurality of openings 13 and the intervals therebetween can be appropriately selected. The openings are preferably disposed such that the whole surface of the wafer W is provided like a mirror. For example, the distance between the most adjacent openings 13 among the plurality of openings 13 is 10 mm or less. The distance between the most adjacent openings 13 among the plurality of openings 13 is preferably 0.01 mm or more. In addition, for example, the openings 13 are disposed such that in a case where a circle having a radius of 10 mm is drawn around all the openings 13 among the plurality of openings 13, all positions of the wafer W to be placed are included in any of the circles. Some of the openings 13 are preferably provided at a position corresponding to the center of the wafer W.

The shape of the opening 13 is not particularly limited. The opening 13 has, for example, a circular shape in plan view. In a case where the opening 13 has a circular shape in plan view, the diameter thereof can be preferably set to 1 mm or less. The diameter is more preferably 0.4 mm or less, and even more preferably 0.1 mm or less. A lower limit of the diameter is preferably 0.01 mm. For example, in a case where the opening 13 has an irregular shape in plan view, the width of the major axis of the opening 13 in plan view is preferably 1 mm or less. The width of the major axis is more preferably 0.4 mm or less, and even more preferably 0.1 mm or less. A lower limit of the width of the major axis is preferably 0.01 mm. The diameter of the opening 13 and the width of the major axis of the opening 13 can be appropriately selected by the arrangement of the openings 13, the flow rate of the rare gas, the temperature, or the like.

As described above, the susceptor 1 according to the present embodiment can sufficiently supply a rare gas to the back surface Wb of the wafer W through the plurality of openings 13, and can suppress the roughness of the back surface Wb of the wafer W. The flow rate of the rare gas to be supplied can be adjusted with the arrangement, the size, or the like of the openings 13, and it is possible to adjust a suppression range of the roughness of the back surface by one opening 13.

In growing a SiC epitaxial film, a raw material gas (Si-based gas and C-based gas), a carrier gas, an etching gas, or the like is supplied toward the wafer W. Some of the gas flows to the back surface Wb of the wafer W. One cause of the roughness of the back surface is the flowing of the gas supplied to grow the SiC epitaxial film to the back surface Wb. Furthermore, in a case where a gas having an effect of etching the wafer W, such as a hydrogen gas, is supplied to the back surface Wb of the wafer W, it may cause the roughness of the back surface Wb of the wafer W. In addition, for example, in a case where some of the raw material gas flows to the back surface Wb of the wafer W, a balance between the Si-based gas and the C-based gas may be lost, and an epitaxial film having poor crystallinity may be formed on the back surface Wb. The epitaxial film having poor crystallinity may cause the roughness of the back surface Wb of the wafer W.

The susceptor 1 according to the present embodiment supplies a rare gas to the back surface Wb of the wafer W. The rare gas supplied to the back surface Wb of the wafer W prevents various gases from flowing to the back surface Wb of the wafer W. As a result, the susceptor 1 according to the present embodiment can suppress the roughness of the back surface Wb of the wafer W.

### Second Embodiment

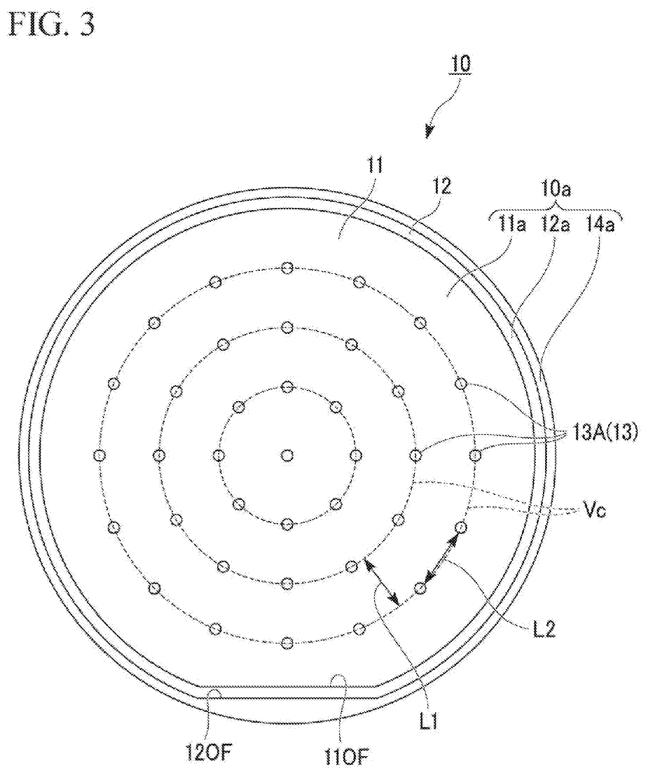

FIG. 3 is a plan view of a susceptor 10 according to a second embodiment. The susceptor 10 according to the second embodiment is different from the susceptor 1 shown in FIG. 2 in the arrangement of openings 13 (13A). In FIG. 3, the same configurations as those of the susceptor 1 shown in FIG. 2 are denoted by the same reference numerals, and description thereof is omitted.

As shown in FIG. 3, a plurality of openings 13A are arranged along a plurality of virtual circles Vc existing concentrically from the center in plan view of a first surface 10a. The openings 13A means through-holes arranged along a plurality of virtual circles Vc and having the same shape as the openings 13.

The plurality of virtual circles Vc exist at regular intervals from the center of the susceptor 10. A distance L1 between adjacent virtual circles Vc is, for example, preferably 10 mm or less, and more preferably 5 mm or less. A lower limit of the distance L1 is preferably 0.01 mm. In a case where the distance L1 between the adjacent virtual circles Vc is within this range, a rare gas can be sufficiently supplied to a whole back surface Wb of a wafer W. The plurality of virtual circles Vc are preferably equally spaced from each other. The distance L between adjacent virtual circles Vc is a distance in a radial direction between an virtual circle Vc and an virtual circle Vc adjacent thereto.

For example, the openings 13A are positioned at equal intervals in a circumferential direction of the virtual circle Vc. A distance L2 between adjacent openings 13A in the circumferential direction is, for example, preferably 10 mm or less, and more preferably 5 mm or less. A lower limit of the distance L2 is preferably 0.01 mm. In a case where the distance L2 between adjacent openings 13A in the circumferential direction is within this range, a rare gas can be sufficiently supplied to the whole back surface Wb of the wafer W. The distance L2 between adjacent openings 13A in the circumferential direction is the shortest distance between two adjacent openings 13A arranged on the same virtual circle Vc. The openings 13A is also preferably arranged at the center of the susceptor 10.

Other configurations of the susceptor 10 may be the same as those of the susceptor 1.

### Third Embodiment

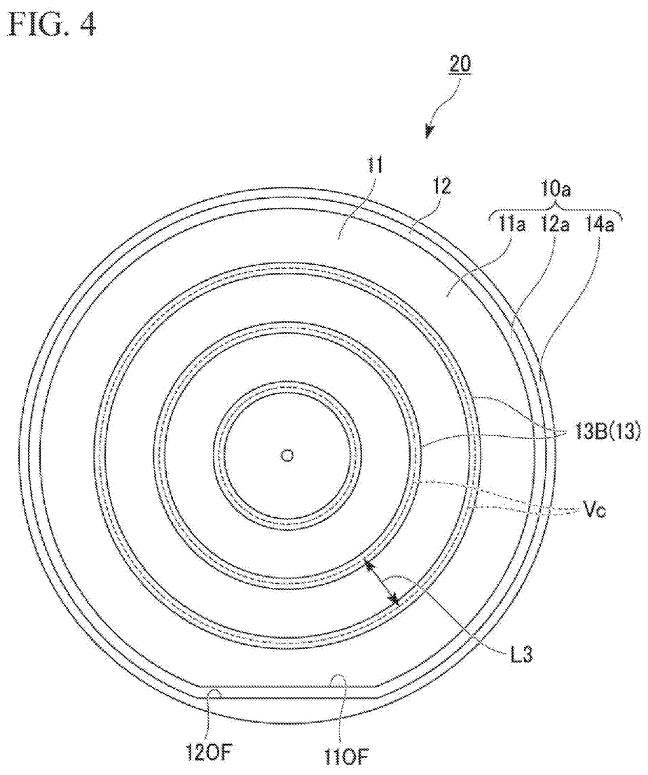

FIG. 4 is a plan view of a susceptor 20 according to a third embodiment. The susceptor 20 according to the third embodiment is different from the susceptor 10 shown in FIG. 3 in the shape of the openings 13 (13A, 13B). In FIG. 4, the same configurations as those of the susceptor 10 shown in FIG. 3 are denoted by the same reference numerals, and description thereof is omitted.

As shown in FIG. 4, a plurality of openings 13B are arranged along a plurality of virtual circles Vc existing concentrically from the center in plan view of a first surface 10a. In FIG. 4, each of the plurality of openings 13B are through-holes having a ring shape which continues along the virtual circle Vc (hereinafter, referred to as circular ring openings 13B). The circular ring openings 13B may be arranged in a portion other than the portion along the virtual circle Vc, and the susceptor 20 may have openings 13A at the same time.

The circular ring openings 13B exist concentrically from the center of the susceptor 20 at regular intervals. A distance L3 between adjacent circular ring openings 13B is, for example, preferably 10 mm or less, and more preferably 5 mm or less. A lower limit of the distance L3 is preferably 0.01 mm. In a case where the distance L3 between adjacent circular ring openings 13B is within this range, a rare gas can be sufficiently supplied to the whole back surface Wb of the wafer W. The circular ring openings 13B are preferably equally spaced from each other. The distance L3 between adjacent circular ring openings 13B is a distance in a radial direction between a circular ring opening 13B and a circular ring opening 13B adjacent thereto.

An opening is also preferably provided at the center of the susceptor 20.

The width of the circular ring opening 13B, that is, the width of the circular ring opening 13B in the radial direction is preferably 1 mm or less, and more preferably 0.4 mm or less. The width is even more preferably 0.1 mm or less since it is possible to prevent the temperature state in the vicinity of the circular ring openings 13B varying greatly. A lower limit of the width of the circular ring opening 13B is preferably 0.01 mm.

The susceptor 20 according to the third embodiment can sufficiently supply a rare gas to the back surface Wb of the wafer W through the plurality of circular ring openings 13B, and can suppress the roughness of the back surface Wb of the wafer W.

### Fourth Embodiment

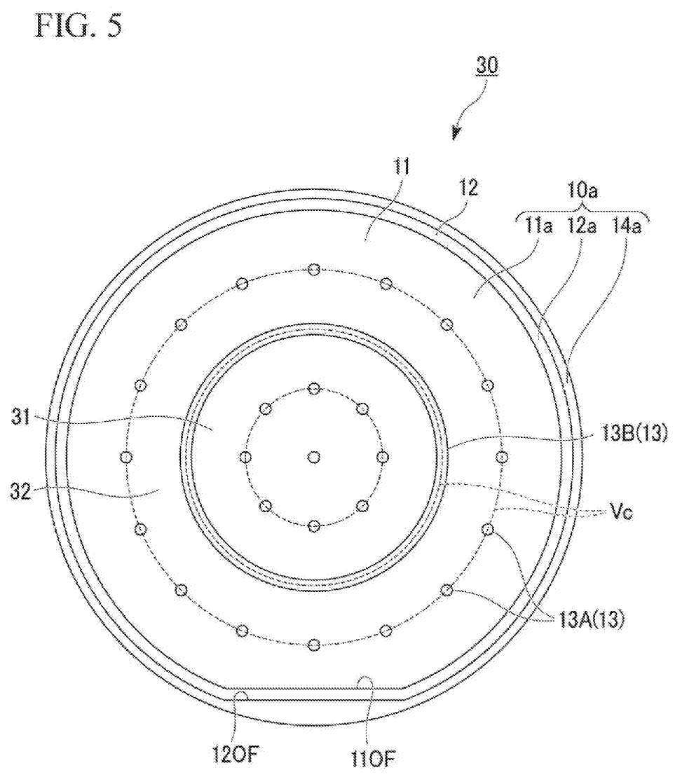

FIG. 5 is a plan view of a susceptor 30 according to a fourth embodiment. The susceptor 30 according to the fourth embodiment is different from the susceptor 10 shown in FIG. 3 in the shape of an opening 13 (13A, 13B). In FIG. 5, the same configurations as those of the susceptor 10 shown in FIG. 3 are denoted by the same reference numerals, and description thereof is omitted.

As shown in FIG. 5, a plurality of openings 13 are arranged along a plurality of virtual circles Vc existing concentrically from the center in plan view of a first surface 10a. In FIG. 5, the plurality of openings 13 include one circular ring opening 13B which continues along the virtual circle Vc and a plurality of openings 13A which are scattered along the virtual circle Vc. The susceptor 30 shown in FIG. 5 has a combination of the openings 13A according to the second embodiment and the circular ring opening 13B according to the third embodiment.

The susceptor 30 is separated into a first portion 31 and a second portion 32 by one circular ring opening 13B. The first portion 31 is positioned inside the susceptor 30 from the second portion 32. The first portion 31 may be moved up and down by, for example, a vertical drive mechanism (push-up mechanism). The second portion 32 and a wafer W can be separated from each other by moving the first portion 31 upward. In a case where the second portion 32 and the wafer W are separated from each other, the wafer W is easily attached or removed during transportation.

The susceptor 30 according to the fourth embodiment can sufficiently supply a rare gas to the back surface Wb of the wafer W through the openings 13A and the circular ring opening 13B, and can suppress the roughness of the back surface Wb of the wafer W.

### Fifth Embodiment

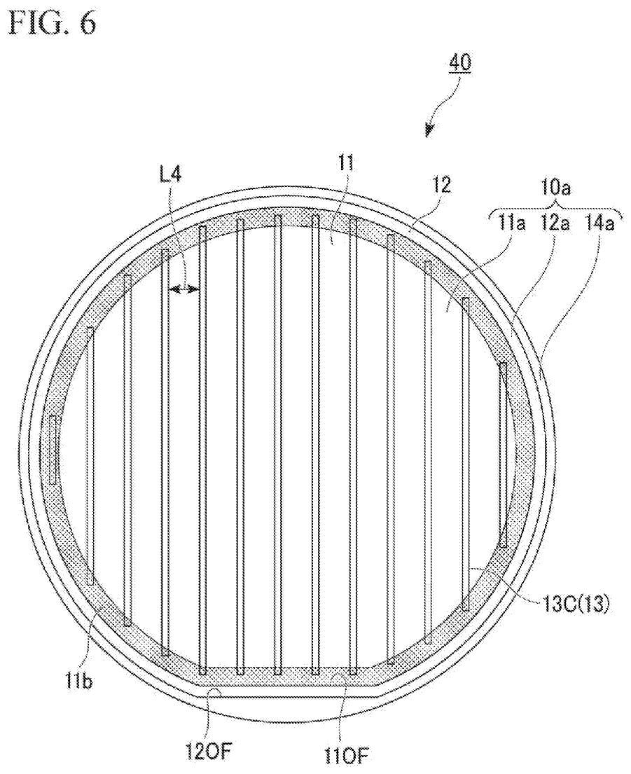

FIG. 6 is a plan view of a susceptor according to a fifth embodiment. A susceptor 40 according to the fifth embodiment is different from the susceptor 10 shown in FIG. 3 in the shape of an opening 13 (13C). In FIG. 6, the same configurations as those of the susceptor shown in FIG. 3 are denoted by the same reference numerals, and description thereof is omitted.

Some of openings 13C of the susceptor 40 according to the fifth embodiment have a long axis in plan view. The openings 13C are through-holes having a rectangular shape containing the long axis in plan view (hereinafter, referred to as rectangular openings 13C). FIG. 6 shows that all the openings 13 are the rectangular openings 13C, but the openings 13 may be a combination of the rectangular opening 13C and the openings 13A or the circular ring openings 13B.

Some of the openings 13 of the susceptor 40 according to the fifth embodiment are a rectangular opening 13C. The rectangular openings 13C are arranged at regular intervals in the susceptor 40. A distance L4 between adjacent rectangular openings 13C is, for example, preferably 10 mm or less, and more preferably 5 mm or less. A lower limit of the distance L4 is preferably 0.01 mm The rectangular openings 13C are preferably equally spaced from each other. The distance L4 between adjacent rectangular openings 13C is a distance between a rectangular opening 13C and a rectangular opening 13C adjacent thereto.

The width of the rectangular opening 13C (a short axis of the rectangular opening 13C) is preferably 1 mm or less, and more preferably 0.4 mm or less. A lower limit of the width is preferably 0.01 mm. The width is even more preferably 0.1 mm or less since it is possible to prevent the temperature state in the vicinity of the rectangular openings 13C varying greatly. The widths of the plurality of rectangular openings 13C may be different from each other.

The length of the rectangular opening 13C (a long axis of the rectangular opening 13C) is preferably a length connecting two points on a region of an outer peripheral portion 11b of a main body 11. The outer peripheral portion 11b of the main body part 11 refers to a region of 10 mm from an outer peripheral end of the main body 11 in a direction toward the center. The outer peripheral portion 11b of the main body part 11 may refer to a region of 1 mm from the outer peripheral end of the main body 11 in a direction toward the center. The lengths of the plurality of rectangular openings 13C may be different from each other.

The rectangular opening 13C may not be a continuous opening on the same straight line, but be a plurality of openings intermittently positioned in the same straight line. In addition, rectangular openings 13C in various directions may be combined. In the susceptor 40 shown in FIG. 6, all the openings 13 are the rectangular openings 13C, but the openings 13 may be a combination of the rectangular openings 13C and openings having various shapes such as the openings 13A or the circular ring openings 13B.

The rectangular opening 13C according to the present embodiment is not limited to the above forms. The rectangular opening 13C is an example of an opening having a long axis in plan view. The opening having a long axis in plan view may have a trapezoidal or elliptical shape. In a case where the openings according to the present embodiment have the above configuration, it is possible to suppress the roughness of the back surface of the wafer W to be placed and to grow a SiC epitaxial wafer.

### Sixth Embodiment

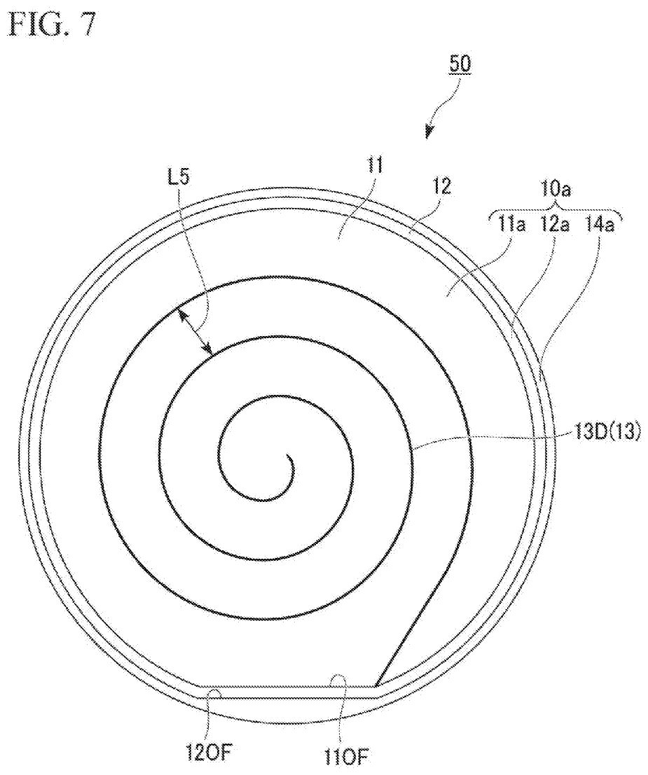

FIG. 7 is a plan view of a susceptor 50 according to a sixth embodiment. The susceptor 50 according to the sixth embodiment is different from the susceptor 10 shown in HG. 3 in the shape of an opening 13 (13D). In FIG. 7, the same configurations as those of the susceptor 10 shown in FIG. 3 are denoted by the same reference numerals, and description thereof is omitted.

As shown in FIG. 7, the opening 13D is a through-hole continues from the center toward the outer periphery in plan view of a first surface 10a. The opening 13D is formed in a spiral shape in plan view of the first surface 10a (hereinafter, referred to as a spiral opening 13D).

The spiral opening 13D is preferably formed through the center of the susceptor 50.

A distance L5 in a radial direction between adjacent spiral opening 13D is, for example, preferably 10 mm or less, and more preferably 5 mm or less. A lower limit of the distance L5 is preferably 0.01 mm. In a case where the distance L5 in a radial direction between adjacent spiral openings 13D is within this range, a rare gas can be sufficiently supplied to the whole back surface Wb of the wafer W. The distance L5 in a radial direction between adjacent spiral openings 13D is a distance between adjacent openings when the susceptor 50 is cut at a cutting face passing through the center of the susceptor.

The width of the spiral openings 13D, that is, the width of the spiral openings 13D in the radial direction is preferably 1 mm or less, and more preferably 0.4 mm or less. The width is even more preferably 0.1 mm or less since it is possible to prevent the temperature state in the vicinity of the spiral openings 13D varying greatly. A lower limit of the width of the spiral openings 13D is preferably 0.01 mm.

The susceptor 50 according to the sixth embodiment can sufficiently supply a rare gas to the back surface Wb of the wafer W through the spiral opening 13D, and can suppress the roughness of the back surface Wb of the wafer W.

<Chemical Vapor Deposition Apparatus>

### Seventh Embodiment

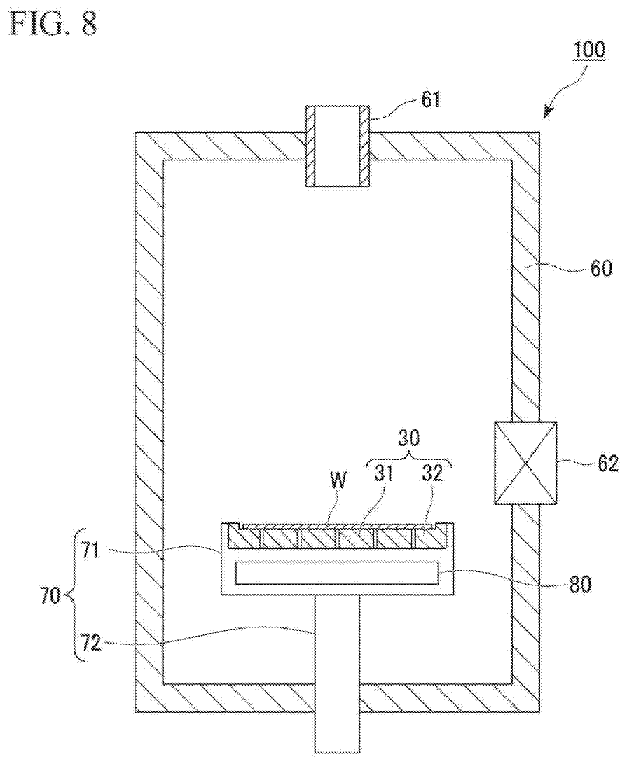

FIG. 8 is a schematic cross-sectional view showing an example of a chemical vapor deposition apparatus according to a seventh embodiment.

FIG. 8 shows a state where a susceptor 30 is placed on a support 70 and a wafer W is placed on the susceptor 30 for easy understanding.

A chemical vapor deposition apparatus 100 according to the seventh embodiment has a furnace body 60, a support 70, and a heater 80.

The furnace body 60 has a gas supply pipe 61, a gas exhaust port (not shown), and a transport port 62. As materials of the furnace body 60, known materials can be used as long as they can withstand high temperatures. For example, C, SiC, metal carbide, C coated with SiC or metal carbide, stainless steel, and the like can be used.

The gas supply pipe 61 supplies a raw material gas or the like into the furnace body 60. The supplied raw material gas is supplied to the wafer W placed on the susceptor 30 on the support 70.

The gas supply pipe 61 supplies a raw material gas, a carrier gas, a doping gas, a rare gas, and the like. A known Si-based gas and a C-based gas can be used as a raw material gas. Nitrogen and the like can be used as a carrier gas and a doping gas.

The support 70 has a placement portion 71 and a support column 72. The placement portion 71 may include a vertical drive mechanism. The placed susceptor 30 and the wafer W on the susceptor 30 are driven up and down, and can be easily removed during transport.

In a case where the placement portion 71 has a vertical drive mechanism, the vertical drive mechanism drives the susceptor 30 up and down. The vertical drive mechanism drives a first portion 31 of the susceptor 30 up and down. The wafer W is transported from the transport port 62 into the furnace body 60. Since only the first portion 31 is moved upward, it is possible to prevent a second portion 32 being brought into contact with the transport mechanism during transport, and the wafer W is easily transported. Due to the above configuration, it is possible to transport the wafer W without cooling the furnace body 60 at a high temperature. Moreover, re-heating to a high temperature is not required after transport. Therefore, the throughput in the epitaxial wafer manufacturing can be improved.

The support 70 is rotated in a circumferential direction. In a case where the support 70 is rotated, the susceptor 30 placed on the support 70 is rotated.

The support 70 can be rotated in the circumferential direction. Accordingly, in a case where the susceptor 30 on which the wafer W has been placed is placed on the support 70, the wafer W is rotated during epitaxial growth, and a raw material gas can be supplied evenly to the wafer W. Accordingly, an epitaxial wafer having high in-plane uniformity can be manufactured.

The heater 80 is provided inside the support 70. A rare gas which protects the heater 80 is supplied around the heater 80. The rare gas is supplied to the back surface of the wafer W via openings 13 (13A, 133B) of the susceptor 30.

The heater 80 heats the inside of the furnace body 60 to a high temperature.

The impurity concentration of a member installed around the space where the rare gas is supplied, that is, around the heater 80 is preferably low. For example, the impurity concentration is preferably 0.1 ppmw or less, and more preferably 0.01 ppmw or less. Impurities consist of, for example, B or Al. In a case where a rare gas is supplied in a direction toward the back surface of the wafer W to be placed via an opening 13B of the susceptor 30 in a state where there are a large number of impurities around the heater 80, there is a concern that the impurities may flow to the surface of the wafer W. It is not preferable that the impurities flow to the surface of the wafer W since there is a concern that the quality of a SiC epitaxial wafer to be manufactured may be deteriorated.

In the chemical vapor deposition apparatus 100 according to the seventh embodiment, a rare gas which protects the heater 80 is supplied to a back surface of a wafer W via the opening 13(13A, 13B) of the susceptor 30. Therefore, the chemical vapor deposition apparatus 100 according to the seventh embodiment can suppress the roughness of a back surface Wb of the wafer W.

### EXAMPLES

### Example 1

In a susceptor according to Example 1, a susceptor 20 (see FIG. 4) according to the third embodiment has one circular ring opening 13B. The susceptor according to the first embodiment is separated into a first portion inside the circular ring opening and a second portion outside the circular ring opening. The circular ring opening arranged at the circumference of a circle centered at the center of the susceptor had a radius of 40 mm, and the width in a radial direction of the circular ring opening was 0.4 mm

A 6-inch SiC wafer was placed on a first surface of the susceptor according to Example 1, and a SiC epitaxial film was grown on a main surface of the SiC wafer by chemical vapor deposition. An Ar gas was supplied to the back surface side of the susceptor to protect the heater during the growth of the SiC epitaxial film. Some of the Ar gas was supplied to the back surface side of the wafer via the circular ring opening of the susceptor. The flow rate of the Ar gas flowing out from the circular ring opening was about 5 sccm. In Example 1, the thickness of the grown epitaxial film is 30 μm.

FIG. 9 is a diagram showing the surface roughness of the back surface of the wafer after the formation of the epitaxial film. In FIG. 9, the horizontal axis represents a distance from the circular ring opening in the radial direction, and the vertical axis represents surface roughness of the back surface of the wafer. A position “0 mm” in the horizontal axis indicates a position of the wafer corresponding to a position of the circular ring opening and the positive direction of the horizontal axis is a direction toward the center of the wafer from the circular ring opening. The surface roughness of the back surface of the wafer was measured using the Haze map function of a surface inspection apparatus (SICA) manufactured by Lasertec Co., Ltd. In the present example, the measurement was performed using the Haze map of the surface inspection apparatus (SICA) manufactured by Lasertec Co., Ltd., but the observation may be performed using an apparatus having a similar principle, such as a white light interferometer system (Zygo) manufactured by Zygo Corporation.

As shown in FIG. 9, the surface roughness of the back surface of the wafer was low in the vicinity of the circular ring opening. The reason for this is thought to be that supply of a raw material gas (Si-based gas and C-based gas), a carrier gas, an etching gas, or the like to the back surface of the wafer is inhibited by supplying an Ar gas via the circular ring opening. Particularly, the back surface of the wafer had high specularity within a range of 10 mm inside the circular ring opening.

Accordingly, in a case where the circular ring opening is disposed concentrically at intervals of 10 mm, the back surface of the wafer can be provided like a mirror. The interval between the circular ring openings can be changed according to the amount of Ar to be supplied.

The surface roughness of the back surface of the wafer is different between the inside and the outside of the circular ring opening. The reason for this is thought to be that the raw material gas (Si-based gas and C-based gas), the carrier gas, the etching gas, and the like are supplied from the outer peripheral side of the wafer. It is thought that in a case where the circular ring opening is inclined toward the inside or the outside of the susceptor, the flow direction of the rare gas can be controlled, and supply of the carrier gas, the etching gas, or the like can be further inhibited.

### Example 2

In a susceptor according to Example 2, only one opening 13 is provided at the center. The opening is circular, and the width of the opening in a radial direction, that is, the diameter of the opening is 1.0 mm.

A 6-inch SiC wafer was placed on a first surface of the susceptor according to Example 2 , so that a center of the wafer corresponded to the center of the susceptor, and a SiC epitaxial film was grown on a main surface of the SiC wafer by a chemical vapor deposition apparatus. An Ar gas was supplied to the back surface side of the susceptor to protect the heater during the growth of the SiC epitaxial film. Some of the Ar gas was supplied to the back surface side of the wafer via the opening of the susceptor. The flow rate of the Ar gas flowing out from the opening was about 5 sccm. In Example 2, the thickness of the grown epitaxial film is 10 μm.

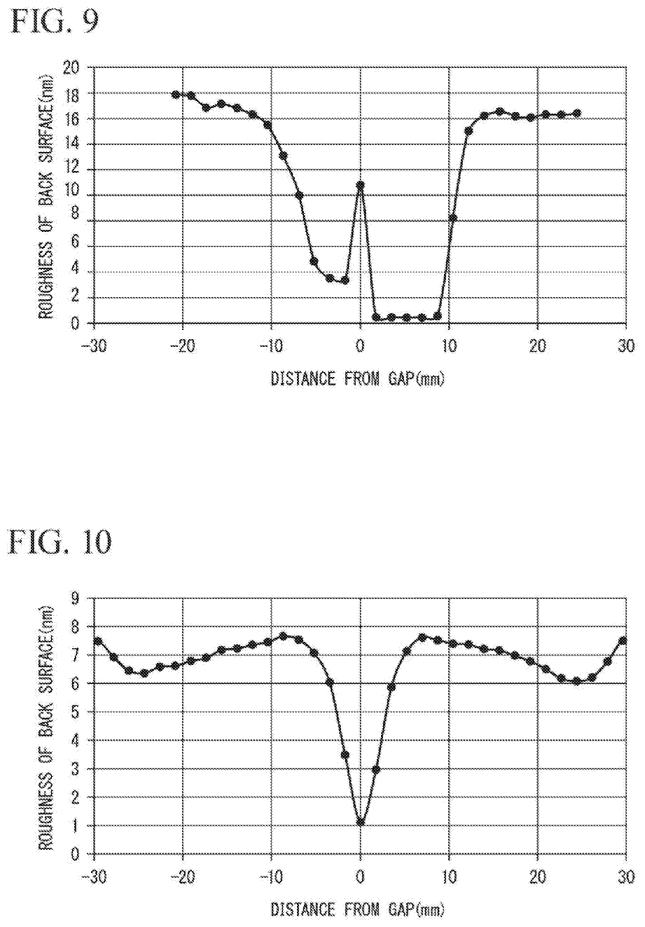

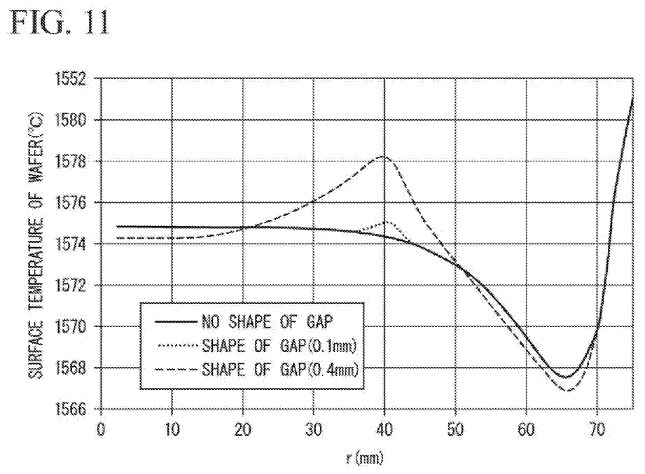

FIG. 10 is a diagram showing the surface roughness of the back surface of the wafer after the formation of the epitaxial film. The horizontal axis represents a distance from the center of the wafer, and the vertical axis represents surface roughness of the back surface of the wafer. The positive direction of the horizontal axis is one radial direction of the wafer. The surface roughness of the back surface of the wafer was measured using the Haze map function of a surface inspection apparatus (SICA) manufactured by Lasertec Co., Ltd. In the present example, the measurement was performed using the Haze map of the surface inspection apparatus (SICA) manufactured by Lasertec Co., Ltd., but the observation may be performed using an apparatus having a similar principle, such as a white light interferometer system (Zygo) manufactured by Zygo Corporation.

As shown in FIG. 10, the roughness of the back surface of the wafer was low around the opening provided at the center of the susceptor. The reason for this is thought to be that supply of a raw material gas (Si-based gas and C-based gas), a carrier gas, an etching gas, or the like to the back surface of the wafer is inhibited by supplying an Ar gas via the opening.

### Reference Examples 1 to 3

In Reference Examples 1 to 3, changes in the temperature distribution of wafers in a case where a width in a radial direction of a circular ring opening 13B was changed were measured through simulation. Reference Example 1 is a temperature distribution of the wafer in which the circular ring opening 13B is not provided, Reference Example 2 is a temperature distribution of the wafer in which the width in a radial direction of the circular ring opening 13B is 0.1 mm, and Reference Example 3 is a temperature distribution of the wafer in which the width in a radial direction of the circular ring opening 13B is 0.4 mm.

FIG. 11 shows the results obtained by measuring, through simulation, changes in the temperature distribution of the wafers of Reference Examples 1 to 3 in a case where the width in a radial direction of the circular ring opening 13B is changed. As shown in FIG. 11, in a case where the width of the circular ring opening 13B was 0.4 mm, the wafer temperature in the vicinity of the circular ring opening 13B increased. The reason for this is thought to be that the radiation rate of the susceptor changed due to the groove of the circular ring opening 13B. Si is more easily sublimated than C. Therefore, in a case where the temperature of the wafer is high, Si sublimates, the crystallinity of the back surface of the SiC wafer decreases, and the surface roughness decreases. The reason why the surface roughness of the back surface of the wafer directly above the circular ring opening 13B locally increased in FIG. 9 is thought to be due to the above phenomenon. In other words, the surface roughness of the back surface of the wafer can be further reduced in a case where the width in a radial direction of the circular ring opening 13B is 0.1 mm or less.

As described above, since a susceptor according to the present invention has a plurality of openings penetrating through the susceptor in a thickness direction, the susceptor can suppress the occurrence of the roughness of a back surface of a wafer in film formation on the wafer by chemical vapor deposition, and can provide a SiC epitaxial wafer in which defocusing or peeling of the back oxide film hardly occurs.

### EXPLANATION OF REFERENCES

1, 10, 20, 30, 40, 50: SUSCEPTOR

10a: FIRST SURFACE

10b: SECOND SURFACE

11: MAIN BODY

12: PROTRUSION

13: OPENING

13A: OPENING

13B: CIRCULAR RING OPENING

13C: RECTANGULAR OPENING

13D: SPIRAL OPENING

14: OUTER PERIPHERAL PROTRUSION

31: FIRST PORTION

32, SECOND PORTION

60: FURNACE BODY

70: SUPPORT

71: PLACEMENT PORTION

72: SUPPORT COLUMN

80: HEATER

Vc: VIRTUAL CIRCLE

W: WAFER

Wb: BACK SURFACE

What is claimed is:

1. A susceptor, comprising:
a base portion having a first surface on which a wafer is placed,
wherein the base portion has a plurality of openings which penetrate through the base portion in a thickness direction and supply an Ar gas to a back surface of the wafer.

2. The susceptor according to claim 1,
wherein the base portion is provided with a main body and a protrusion,
the plurality of openings are provided in the main body, and
the protrusion protrudes from the main body in a thickness direction and is provided at an outer periphery of the base portion.

3. The susceptor according to claim 1,
wherein the plurality of openings are arranged along a plurality of virtual circles existing concentrically from a center in plan view of the first surface.

4. The susceptor according to claim 2,
wherein the plurality of openings are arranged along a plurality of virtual circles existing concentrically from a center in plan view of the first surface.

5. The susceptor according to claim 3,
wherein a distance between the adjacent virtual circles is 10 mm or less.

6. The susceptor according to claim 4,
wherein a distance between the adjacent virtual circles is 10 mm or less.

7. The susceptor according to claim 3,
wherein some of the plurality of openings are provided as a circular ring opening which continues along the virtual circle.

8. The susceptor according to claim 3,
wherein some of the plurality of openings are provided as through-holes which are scattered along the virtual circle.

9. The susceptor according to claim 1,
wherein at least some of the plurality of openings have a long axis in plan view.

10. The susceptor according to claim 1,
wherein the opening has a width of 1 mm or less.

11. A susceptor which is used in a chemical vapor deposition apparatus which grows an epitaxial film on a main surface of a wafer by chemical vapor deposition, comprising:
a first surface on which the wafer is placed; and
an opening which penetrates through the susceptor in a thickness direction toward the first surface and supplies a rare gas to the wafer,
wherein the opening is a spiral opening formed in a spiral shape from a center toward an outer periphery in plan view of the first surface.

12. The susceptor according to claim 11,
a distance in a radial direction between the adjacent spiral openings is 10 mm or less.

13. A chemical vapor deposition apparatus, comprising:
the susceptor according to claim 1.

14. A chemical vapor deposition apparatus, comprising:
the susceptor according to claim 11.
